(19) United States
(12) Patent Application Publication
(10) Pub. No.: US 2025/0246565 A1
(43) Pub. Date: Jul. 31, 2025

(54) BOND STRUCTURE FOR STACKED IC CHIPS

(71) Applicant: Taiwan Semiconductor Manufacturing Company, Ltd., Hsinchu (TW)

(72) Inventors: Tzu-Ming Wang, Tainan City (TW); Yen-Yu Chen, Kaohsiung City (TW); Yen-Ting Chiang, Tainan City (TW); Wen-Chang Kuo, Tainan City (TW); Jen-Cheng Liu, Hsin-Chu City (TW)

(21) Appl. No.: 18/752,974

(22) Filed: Jun. 25, 2024

Related U.S. Application Data
(60) Provisional application No. 63/627,107, filed on Jan. 31, 2024.

(51) Int. Cl. H01L 23/00; H01L 27/146

(52) U.S. Cl. CPC H01L 24/06; H01L 24/08; H10F 39/809; H10F 39/811; H01L 24/05; H01L 2224/0555; H01L 2224/06132; H01L 2224/06517; H01L 2224/08146; H10F 39/018

(57) ABSTRACT

Various embodiments of the present disclosure are directed towards a device including an interconnect structure over a substrate. A bond structure is over the interconnect structure. The bond structure includes a first plurality of conductive bond pads disposed in a first region and a second plurality of conductive bond pads disposed in a second region. The second region is adjacent to at least one side of the first region. A first pitch of the first plurality of conductive bond pads is less than a second pitch of the second plurality of conductive bond pads.

### REFERENCE TO RELATED APPLICATION

This application claims the benefit of U.S. Provisional Application No. 63/627,107, filed on Jan. 31, 2024, the contents of which are hereby incorporated by reference in their entirety.

### BACKGROUND

Many modern-day electronic devices (e.g., smartphones, digital cameras, biomedical imaging devices, automotive imaging devices, etc.) comprise image sensors. The image sensors comprise one or more photodetectors (e.g., photodiodes, phototransistors, photoresistors, etc.) configured to absorb incident radiation and output electrical signals corresponding to the incident radiation. Image sensors may comprise stacked chips to decrease a footprint of each pixel and increase device density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate various views of some embodiments of a stacked integrated circuit (IC) device comprising a bond structure having first conductive bond pads arranged with a first pitch and second conductive bond pads arranged with a second pitch different from the first pitch.

FIGS. 2A and 2B illustrate various views of some other embodiments of the stacked IC device of FIGS. 1A and 1B.

FIGS. 3A and 3B illustrate various views of some further embodiments of the stacked IC device of FIGS. 1A and 1B.

FIGS. 4A and 4B illustrate various views of some embodiments of a stacked IC device comprising a bond structure having conductive bond pads with varying pitches disposed across a first region, a second region, and a third region.

FIGS. 5A-5H illustrate various cross-sectional views of some other embodiments of the stacked IC device of FIGS. 4A and 4B.

FIG. 6 illustrates a cross-sectional view of some embodiments of a stacked IC device comprising a bond structure having first conductive bond pads arranged with a first pitch and second conductive bond pads arranged with a second pitch different from the first pitch.

FIG. 7 illustrates a cross-sectional view of some embodiments of a stacked IC device comprising a bond structure having conductive bond pads with varying pitches disposed across a first region, a second region, and a third region.

FIG. 8 illustrates a top view of some embodiments of a bond structure of an IC chip having conductive bond pads with varying pitches disposed across a first region, a second region, and a third region.

FIGS. 9A-9C illustrates various top views of some embodiments of the conductive bond pads in the first, second and third regions of FIG. 8.

FIG. 10A illustrates a cross-sectional view of some embodiments of a stacked IC device comprising a first IC chip, a second IC chip, and a third IC chip vertically stacked with one another.

FIG. 10B illustrates a cross-sectional view of some embodiments of a stacked IC device comprising a first IC chip, a second IC chip, a third IC chip, and a fourth IC chip vertically stacked with one another.

FIGS. 11-19 illustrate various cross-sectional views of some embodiments of a method of forming a stacked IC device comprising bond structures having conductive bond pads with varying pitches disposed across multiple regions.

FIG. 20 illustrates a method of some embodiments of forming a stacked IC device comprising bond structures having conductive bond pads with varying pitches disposed across multiple regions.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacked integrated circuit (IC) device may comprise a first integrated circuit (IC) chip and a second IC chip that are vertically stacked with one another. The first IC chip includes a first substrate, a first interconnect structure on the first substrate, and a first bond structure on the first interconnect structure. The stacked IC device may be configured as an image sensor, such that a plurality of photodetectors are disposed in the first substrate. Transfer transistors may be disposed on the first substrate and are configured to transfer accumulated charge from the photodetectors. The second IC chip includes a second substrate, a plurality of semiconductor devices on the second substrate, a second interconnect structure on the second substrate, and a second bond structure on the second interconnect structure. The first bond structure and the second bond structure meet at a bond interface and facilitate coupling electrical signals corresponding to the accumulated charge from the photodetectors to the plurality of semiconductor devices on the second substrate.

The first bond structure may be configured in a number of different ways. For example, the first bond structure may include a plurality of conductive bond pads disposed in a dielectric bond structure. A first region of the first bond structure directly underlies the plurality of photodetectors and the plurality of conductive bond pads are disposed in a second region of the first bond structure. The second region is disposed around the first region, such that the plurality of conductive bond pads are laterally offset from the plurality of photodetectors. However, in such a configuration a number of structures and complexity of conductive interconnects in the first interconnect structure are increased to route electrical signals to the second region laterally offset from the plurality of photodetectors. This increases design complexity and fabrication costs.

In another embodiment, the first bond structure may comprise a first plurality of conductive bond pads in the first region and a second plurality of conductive bond pads in the second region. Further, a plurality of conductive bond vias may be disposed between the first plurality of conductive bond pads and the first interconnect structure, such that the first bond structure has two or more layers of conductive bond structures. However, including the plurality of conductive bond vias increases a number of conductive structures in the first bond structure, thereby increasing fabrication costs of the first IC chip. In addition, the first plurality of conductive bond pads and the second plurality of conductive bond pads are formed with a constant (e.g., uniform) pitch across the first and second regions. Due to limitations in processing tools (e.g., limitations in planarization tools), the second plurality of conductive bond pads in the second region having the same pitch as the first plurality of conductive bond pads may cause height variations in an upper surface (e.g., a bonding surface) of the first bond structure. As a result, the upper surface of the first bond structure may, for example, not be substantially planar and/or a total thickness variation (TTV) of the upper surface is relatively high. This may cause voids and/or bubbling between the first and second IC chips across the bond interface such that there are non-bond regions between the first and second IC chips. Non-bond regions are regions between the first and second IC chips that will not bond together during a bonding process. Therefore, bonding adhesion between the first and second IC chips is reduced and the non-bond regions may result in the stacked IC device failing wafer acceptance testing (WAT) (e.g., due to open circuit issues between the IC chips), thereby reducing a structural integrity and/or yield of the stacked IC device.

Accordingly, various embodiments of the present application are directed towards a stacked IC device having bond structures configured to minimize or prevent non-bond regions between stacked IC chips and decrease design complexity and fabrication costs. The stacked IC device comprises a first IC chip stacked with a second IC chip. The first IC chip comprises a first substrate, a plurality of photodetectors in the first substrate, a first interconnect structure on the first substrate, and a first bond structure on the first interconnect structure. The first bond structure comprises a first plurality of conductive bond pads disposed in a first region and a second plurality of conductive bond pads disposed in a second region. The first region is laterally aligned with the plurality of photodetectors and the second region is adjacent to at least one side of the first region. The first plurality of conductive bond pads are arranged with a first pitch (e.g., a distance between opposing sides of adjacent conductive bond pads) and the second plurality of conductive bond pads are arranged with a second pitch greater than the first pitch. As a result, a first density of conductive bond pads in the first region is greater than a second density of conductive bond pads in the second region. The conductive bond pads in the first region having the first pitch and being laterally aligned with the photodetectors decreases a complexity of routing electrical signals generated from the accumulated charge at the photodetectors. Accordingly, a complexity of and/or number of conductive structures in the first interconnect structure may be decreased, thereby decreasing fabrication costs and increasing a performance of the first IC chip (e.g., by increasing transmission efficiency in the first interconnect structure).

In addition, the second plurality of conductive bond pads in the second region having the second pitch greater than the first pitch facilitates an upper surface (e.g., a bonding surface) of the first bond structure being substantially flat and/or the first IC chip having a relatively low TTV. For example, limitations in processing tools (e.g., limitations in chemical mechanical planarization (CMP) tools) result in less material being removed at peripheral regions of the first IC chip. The lower second density of the conductive bond pads in the second region facilitates a more uniform removal of the conductive bond pads in both the first and second regions of the first bond structure. As a result, the upper surface of the first bond structure is substantially flat and a formation of voids and/or bubbles along a bonding interface between the first and second IC chips are mitigated, thereby mitigating or preventing non-bond regions between the first and second IC chips. Accordingly, the first bond structure having the first plurality of conductive bond pads with the first pitch and the second plurality of conductive bond pads with the second pitch greater than the first pitch increases an overall performance and yield of the stacked IC device.

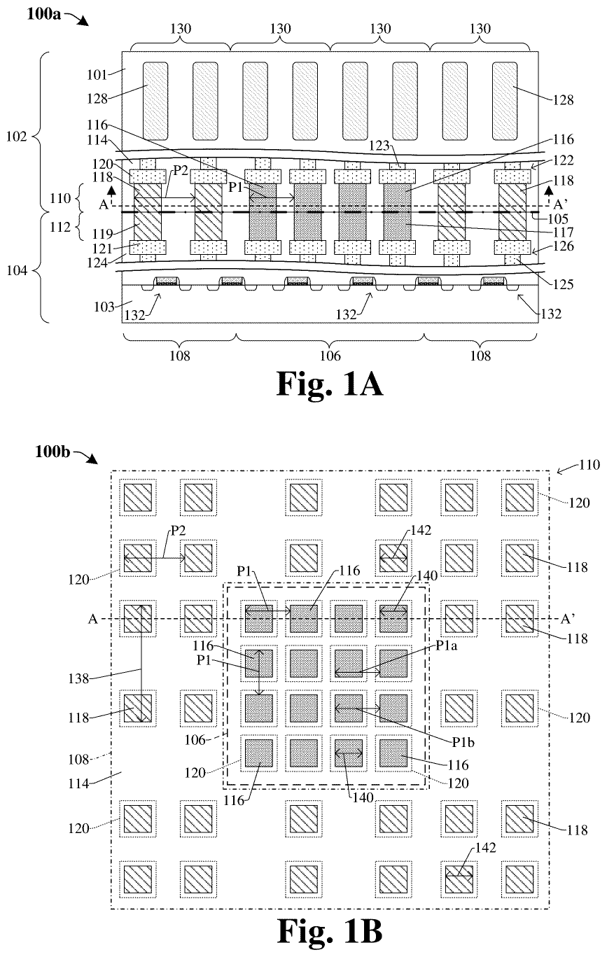

FIGS. 1A and 1B illustrate various views 100a and 100b of some embodiments of a stacked IC device comprising a bond structure having first conductive bond pads arranged with a first pitch and second conductive bond pads arranged with a second pitch different from the first pitch. FIG. 1A illustrates a cross-sectional view 100a of some embodiments of the stacked IC device. FIG. 1B illustrates a top view 100b of some embodiments of the stacked IC device taken along the line A-A′ of FIG. 1A.

The stacked IC device comprises a first IC chip 102 having a first bond structure 110 and a second IC chip 104 having a second bond structure 112. The first bond structure 110 meets the second bond structure 112 at a bond interface 105. The first IC chip 102 further includes a first substrate 101, a first interconnect structure 122 between the first substrate 101 and the first bond structure 110, and a plurality of pixels 130. The plurality of pixels 130 comprise a plurality of photodetectors 128 disposed in the first substrate 101.

The first bond structure 110 comprises a first plurality of conductive bond pads 116 and a second plurality of conductive bond pads 118 disposed in a first dielectric structure 114. The first plurality of conductive bond pads 116 are spaced laterally in a first region 106 of the first substrate 101 and the second plurality of conductive bond pads 118 are spaced laterally in a second region 108 of the first substrate 101. In some embodiments, the first plurality of conductive bond pads 116 and/or the second plurality of conductive bond pads 118 are electrically coupled to the pixels 130 by way of the first interconnect structure 122. The first interconnect structure 122 comprises a first plurality of conductive wires 120 and a first plurality of conductive vias 123.

The second IC chip 104 comprises a second substrate 103, a second interconnect structure 126 between the second substrate 103 and the second bond structure 112, and a plurality of semiconductor devices 132 disposed on the second substrate 103. In some embodiments, the plurality of semiconductor devices 132 may, for example, be or comprise pixel devices (e.g., comprising source-follower transistor(s), select transistor(s), reset transistor(s), etc.), logic devices, capacitors, other suitable semiconductor devices, or the like. The second bond structure 112 overlies the second interconnect structure 126 and is electrically coupled to the plurality of semiconductor devices 132.

The second bond structure 112 comprises a third plurality of conductive bond pads 117 and a fourth plurality of conductive bond pads 119 disposed in a second dielectric structure 124. The third plurality of conductive bond pads 117 are spaced laterally in the first region 106 and the fourth plurality of conductive bond pads 119 are spaced laterally in the second region 108. In some embodiments, the third plurality of conductive bond pads 117 and/or the fourth plurality of conductive bond pads 119 are electrically coupled to the plurality of semiconductor devices 132 by way of the second interconnect structure 126. The second interconnect structure 126 comprises a second plurality of conductive wires 121 and a second plurality of conductive vias 125.

The first plurality of conductive bond pads 116 and the third plurality of conductive bond pads 117 are bonded to one another at the bond interface 105 and the second plurality of conductive bond pads 118 and the fourth plurality of conductive bond pads 119 are bonded to one another at the bond interface 105. As such, the conductive bond pads 116 and/or 118 of the first bond structure 110 and the conductive bond pads 117 and/or 119 of the second bond structure 112 facilitate electrical coupling between the first and second IC chips 102, 104. Further, the first dielectric structure 114 and the second dielectric structure 124 are bonded to one another at the bond interface 105. Accordingly, the bond interface 105 comprises dielectric-to-dielectric bond interface(s) and conductor-to-conductor bond interface(s).

The first region 106 directly underlies the plurality of pixels 130. In some embodiments, the first region 106 is aligned with a center region of the plurality of pixels 130. The second region 108 is adjacent to at least one side of the first region 106. In various embodiments, the second region 108 laterally wraps around the first region 106 and underlies a peripheral region of the plurality of pixels 130. In some embodiments, the conductive bond pads in the first plurality of conductive bond pads 116 are arranged in an array comprising a plurality of rows and a plurality of columns. The first plurality of conductive bond pads 116 are arranged with a first pitch P1. In some embodiments, the first pitch P1 is defined as a distance between a first edge of an individual conductive bond pad in the first plurality of conductive bond pads 116 and a corresponding second edge of an adjacent conductive bond pad in the first plurality of conductive bond pads 116 (e.g., a spacing between left edges of the conductive bond pads or between right edges of the conductive bond pads). Accordingly, the first plurality of conductive bond pads 116 are arranged in the first region 106 with a first density. The conductive bond pads in the second plurality of conductive bond pads 118 are arranged with a second pitch P2. In some embodiments, the first pitch P1 is less than the second pitch P2. In various embodiments, the second plurality of conductive bond pads 118 are arranged in the second region 108 with a second density that is less than the first density.

In various embodiments, the first plurality of conductive bond pads 116 having the first pitch P1 larger than the second pitch P2 facilitates the first density being relatively large (e.g., greater than the second density). The relatively large first density in the first region 106 directly under the plurality of pixels 130 decreases a complexity of routing electrical signals from accumulated charge at the photodetectors 128 to the second IC chip 104. As a result, a design complexity is decreased and a number and/or size of conductive structures (e.g., conductive wires and/or conductive vias) in the first interconnect structure 122 may be decreased, thereby decreasing fabrication costs. Further, decreasing the number and/or size of the conductive structures in the first interconnect structure 122 reduces a resistive-capacitive (RC) delay in the first IC chip 102. Accordingly, a performance of the pixels 130 and the stacked IC device is increased.

Further, the second pitch P2 being greater than first pitch P1 facilitates the second density being relatively small (e.g., less than the first density). The relatively small second density mitigates issues due to limitations in processing tools. For example, limitations in processing tools (e.g., limitations in CMP tools) may result in less material being removed at a peripheral region of the first IC chip 102. The relatively small second density facilitates a more uniform removal of materials (e.g., conductive materials of the second plurality of conductive bond pads 118) across the first bond structure 110 such that a lower surface (e.g., bonding surface) of the first bond structure 110 is substantially flat and a TTV of the first IC chip 102 is reduced. As a result, a presence of non-bond areas across the bond interface 105 due to voids and/or bubbles may be prevented or mitigated. This facilitates a stronger bond and better electrical coupling between the first IC chip 102 and the second IC chip 104, thereby increasing a yield and overall performance of the stacked IC device.

In various embodiments, the first bond structure 110 and the second bond structure 112 respectively comprise a single layer or a single level of conductive elements. For example, the first bond structure 110 comprises a single layer of conductive elements that includes the first plurality of conductive bond pads 116 and the second plurality of conductive bond pads 118 that are disposed along a same plane. In some embodiments, bottom surfaces of the first plurality of conductive bond pads 116 are coplanar with bottom surfaces of the second plurality of conductive bond pads 118 and top surfaces of the first plurality of conductive bond pads 116 are coplanar with top surfaces of the second plurality of conductive bond pads 118. As a result, a number of conductive elements in the first and second bond structures 110, 112 may be reduced, thereby decreasing fabrication costs and/or an RC delay in the stacked IC device.

In various embodiments, the second bond structure 112 has a similar or same layout and/or configuration as illustrated and/or described above in regards to the first bond structure 110. For example, the third plurality of conductive bond pads 117 are arranged in the first region 106 with the first pitch P1 and the fourth plurality of conductive bond pads 119 are arranged in the second region 108 with the second pitch P2. As a result, a complexity of electrical routing in the second IC chip 104 is reduced and a TTV of the second IC chip 104 is reduced.

Accordingly, the second bond structure 112 having conductive bond pads with the first pitch P1 and the second pitch P2 decreases design complexity and increases an overall performance of the stacked IC device.

As illustrated in FIG. 1B, the first plurality of conductive bond pads 116 are disposed in an array comprising a plurality of rows and a plurality of columns. While FIG. 1B illustrates the first plurality of conductive bond pads 116 being disposed in the array with 4 rows and 4 columns, this is merely a non-limiting example and the array may comprise any number of rows and columns. For example, the first plurality of conductive bond pads 116 may comprise 1,000,000 or more conductive bond pads arranged in an array. The second region 108 is adjacent to at least one side of the first region 106. In various embodiments, the second region 108 wraps around an outer perimeter of the first region 106 and is disposed along each side of the first region 106. Thus, the second region 108 may be ring-shaped. In various embodiments, the second plurality of conductive bond pads 118 are arranged in at least one row or one column along a corresponding side of the first region 106. In further embodiments, the second plurality of conductive bond pads 118 are arranged in an array along at least one side of the first region 106.

In various embodiments, the first plurality of conductive bond pads 116 are arranged in the first region 106 with a uniform pitch that comprises the first pitch P1. For example, a spacing is substantially the same between corresponding outer edges of adjacent conductive bond pads in the first plurality of conductive bond pads 116. As used herein, the term “uniform pitch” means a substantially uniform pitch across the first plurality of conductive bond pads 116 within tolerances due to misalignment errors. In some embodiments, the uniform pitch may have values between different pairs of adjacent conductive bond pads that vary due to misalignment errors by approximately 5% (e.g., a pitch P1a of a first pair of conductive bond pads may be between 0.95 and 1.05 times a pitch P1b of a second pair of conductive bond pads). The first plurality of conductive bond pads 116 having the uniform pitch facilitates the first plurality of conductive bond pads 116 having a relatively high first density. The relatively high first density decreases the complexity of routing electrical signals to and/or from the pixels (130 of FIG. 1A), thereby decreasing design complexity of the first interconnect structure (122 of FIG. 1A).

In some embodiments, the second plurality of conductive bond pads 118 are arranged in the second region 108 with a nonuniform pitch. For example, spacing between corresponding outer edges of adjacent conductive bond pads in the second plurality of conductive bond pads 118 may vary across the second region 108. In various embodiments, a minimum pitch in the nonuniform pitch of the second plurality of conductive bond pads 118 is the second pitch P2 that is greater than the first pitch P1. In some embodiments, a pitch 138 between adjacent rows in the second plurality of conductive bond pads 118 is greater than the second pitch P2. In yet further embodiments, the second plurality of conductive bond pads 118 are arranged in the second region 108 with a uniform pitch that comprises the second pitch P2 (not shown). The second plurality of conductive bond pads 118 having at least the second pitch P2 facilitates the second plurality of conductive bond pads 118 having a second density that is less than the first density. For example, a number of conductive bond pads within a first area of the first region 106 is greater than a second number of conductive bond pads within a second area of the second region 108 (where the first area is equal to the second area). In some embodiments, a number of conductive bond pads per square millimeter in the first region 106 is greater than a number of conductive bond pads per square millimeter in the second region 108.

The second plurality of conductive bond pads 118 having the second density mitigates a formation of non-bond regions between the first IC chip (102 of FIG. 1A) and the second IC chip (104 of FIG. 1B) and increases a bonding strength along the bond interface (105 of FIG. 1A), thereby increasing device yield. For example, limitations in processing tools (e.g., CMP tools) may result in an ununiform removal of material from an outer region of an IC chip. In various embodiments, the issue of nonuniformly removing materials may be exacerbated for chips disposed at or around a peripheral region of a semiconductor wafer. The lower second density of the second plurality of conductive bond pads 118 in the second region 108 mitigates issues related to the nonuniform removal of materials at the outer region of the IC chip, such that a TTV of the first IC chip (102 of FIG. 1A) may be reduced. As a result, the formation of voids and/or bubbling along the bond interface (105 of FIG. 1A) is mitigated or prevented, thereby increasing device yield.

In some embodiments, a first width 140 of each of the conductive bond pads in the first plurality of conductive bond pads 116 and a second width 142 of each of the conductive bond pads in the second plurality of conductive bond pads 118 are each less than about 2 micrometers (um), within a range of about 0.25 to 2 um, or some other suitable value. In various embodiments, the first width 140 is equal to the second width 142. In further embodiments, the first width 140 is different from the second width 142. In yet further embodiments, an area of each of the conductive bond pads in the first plurality of conductive bond pads 116 is equal to or approximately equal to (e.g., equal within a degree of error of about 5% or less) an area of each of the conductive bond pads in the second plurality of conductive bond pads 118. In some embodiments, the first pitch P1 is less than about 4 um, within a range of about 0.5 to 4 um, or some other suitable value. In further embodiments, the second pitch P2 is less than about 10 um, within a range of about 0.75 to 10 um, greater than about 4 um, or some other suitable value.

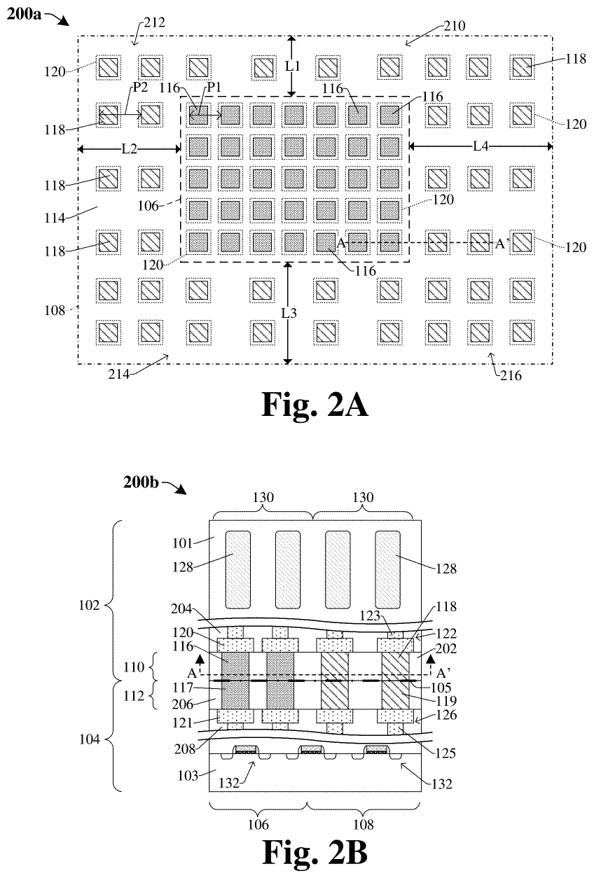

FIGS. 2A and 2B illustrate various views of some other embodiments of the stacked IC device of FIGS. 1A and 1B. FIG. 2A illustrates a top view 200a of some embodiments of the stacked IC device. FIG. 2B illustrates a cross-sectional view 200b of some embodiments of the stacked IC device taken along the line A-A′ of FIG. 2A.

As illustrated in FIG. 2A, in some embodiments, the second region 108 has various subregions with different lengths from the first region 106 to an outer region of the first IC chip (102 of FIG. 2B). For example, the second region 108 has a first subregion 210 having a first length L1, a second subregion 212 having a second length L2, a third subregion 214 having a third length L3, and a fourth subregion 216 having a fourth length L4. The first subregion 210 is disposed along a first side of the first region 106, the second subregion 212 is disposed along a second side of the first region 106, the third subregion 214 is disposed along a third side of the first region 106, and the fourth subregion 216 is disposed along a fourth side of the first region 106. In some embodiments, the first length L1 is less than the second and third lengths L2, L3, and the fourth length L4 is greater than the second and third lengths L2, L3. In various embodiments, the first subregion 210 comprises a single row of the second plurality of conductive bond pads 118. In some embodiments, a center of the first region 106 may be laterally offset from a center of the plurality of pixels (130 of FIG. 2B), where a location of the center of the first region 106 is set to mitigate the complexity of routing electrical signals in the first interconnect structure (122 of FIG. 2B).

As illustrated in FIG. 2B, the first bond structure 110 comprises a first bond dielectric 202 and the first interconnect structure 122 comprises a first interconnect dielectric 204. The first plurality of conductive bond pads 116 and the second plurality of conductive bond pads 118 are disposed in the first bond dielectric 202. The first plurality of conductive wires 120 and the first plurality of conductive vias 123 are disposed in the first interconnect dielectric 204. Further, the second bond structure 112 comprises a second bond dielectric 206 and the second interconnect structure 126 comprises a second interconnect dielectric 208. The third plurality of conductive bond pads 117 and the fourth plurality of conductive bond pads 119 are disposed in the second bond dielectric 206. Further, the second plurality of conductive wires 121 and the second plurality of conductive vias 125 are disposed in the second interconnect dielectric 204.

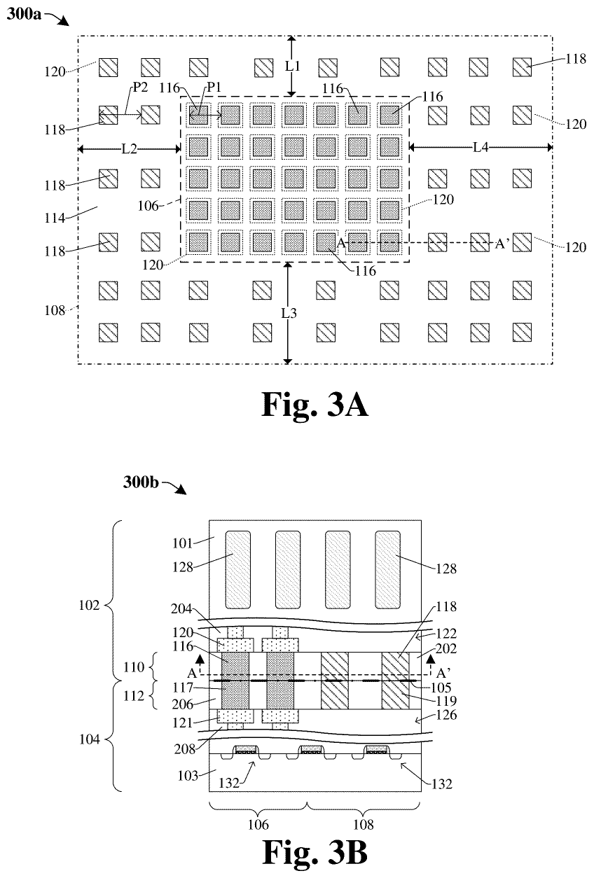

FIGS. 3A and 3B illustrate various views of some other embodiments of the stacked IC device of FIGS. 2A and 2B. FIG. 3A illustrates a top view 300a of some embodiments of the stacked IC device. FIG. 3B illustrates a cross-sectional view 300b of some embodiments of the stacked IC device taken along the line A-A′ of FIG. 3A.

In some embodiments, the second plurality of conductive bond pads 118 are configured as dummy conductive bond pads and are electrically floating. In various embodiments, an entirety of a top surface of each of the conductive bond pads in the second plurality of conductive bond pads 118 directly contact the first interconnect dielectric 204. By virtue of the second plurality of conductive bond pads 118 being configured as dummy conductive bond pads, a strength of the bond along the bond interface 105 is increased while a number of conductive structures in the first interconnect structure 122 may be reduced. As a result, fabrication costs are decreased and a yield of the stacked IC device is increased. In various embodiments, the fourth plurality of conductive bond pads 119 are configured as dummy conductive bond pads and are electrically floating. In various embodiments, an entirety of a bottom surface of each of the conductive bond pads in the fourth plurality of conductive bond pads 119 directly contact the second interconnect dielectric 208.

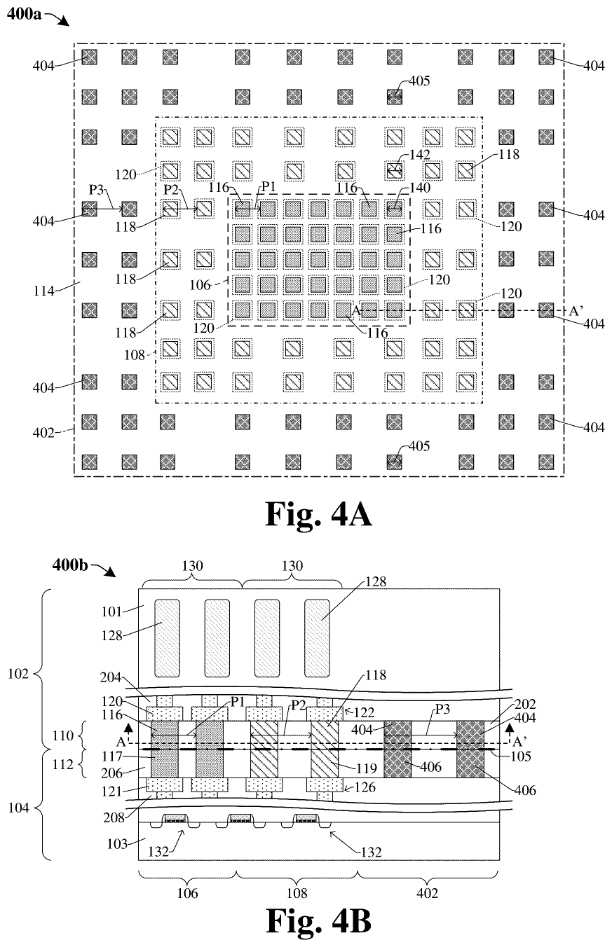

FIGS. 4A and 4B illustrate various views of some embodiments of a stacked IC device comprising a bond structure having conductive bond pads with varying pitches disposed across a first region, a second region, and a third region. FIG. 4A illustrates a top view 400a of some embodiments of the stacked IC device. FIG. 4B illustrates a cross-sectional view 400b of some embodiments of the stacked IC device taken along the line A-A′ of FIG. 4A.

In some embodiments, the first bond structure 110 further comprises a first plurality of outer conductive bond pads 404 arranged in a third region 402 with a third pitch P3. The third pitch P3 is greater than the first pitch P1 and is greater than or equal to the second pitch P2. The third region 402 is disposed along at least one side of the second region 108. In some embodiments, the third region 402 extends around an outer perimeter of the second region 108. In further embodiments, the first plurality of outer conductive bond pads 404 are arranged in the third region with a nonuniform pitch, where a minimum pitch in the nonuniform pitch of the first plurality of outer conductive bond pads 404 is the third pitch P3. In some embodiments, a pitch between at least a pair of rows in the first plurality of outer conductive bond pads 404 is greater than the third pitch P3. Further, the first plurality of outer conductive bond pads 404 are disposed along a same plane as the first plurality of conductive bond pads 116 and the second plurality of conductive bond pads 118. For example, bottom surfaces of the first plurality of outer conductive bond pads 404 are coplanar with bottom surfaces of the first plurality of conductive bond pads 116 and the second plurality of conductive bond pads 118.

In various embodiments, the first region 106 and the second region 108 directly underlie the plurality of pixels 130 and the third region 402 is disposed at an outer region of the first IC chip 102 outside of the plurality of pixels 130. In some embodiments, the first plurality of outer conductive bond pads 404 having at least the third pitch P3 that is greater than the first pitch P1 and the second pitch P2 facilitates the first plurality of outer conductive bond pads 404 having a third density that is less than the first density and less than the second density. For example, a number of conductive bond pads per square millimeter in the third region 402 is less than a number of conductive bond pads per square millimeter in the first region 106 and the second region 108. Accordingly, a density of conductive bond pads in the first bond structure 110 discretely decreases at least twice from a center of the first region 106 to an outer edge of the first bond structure 110. The first plurality of outer conductive bond pads 404 having the third density less than that of the first and second densities further mitigates a formation of non-bond regions between the first IC chip 102 and the second IC chip 104. As a result, a bonding strength along the bond interface 105 and device yield are further increased.

In some embodiments, the first plurality of outer conductive bond pads 404 are configured as dummy conductive bond pads and are electrically floating. In various embodiments, an entirety of a top surface of each of the conductive bond pads in the first plurality of outer conductive bond pads 404 directly contact the first interconnect dielectric 204. Further, the second bond structure 112 further comprises a second plurality of outer conductive bond pads 406 disposed in the third region 402 and are disposed around the fourth plurality of conductive bond pads 119. The second plurality of outer conductive bond pads 406 may be configured as dummy conductive bond pads and are electrically floating.

In some embodiments, a third width 405 of each of the conductive bond pads in the first plurality of outer conductive bond pads 404 is about 2 um, within a range of about 0.25 to 2 um, or some other suitable value. In various embodiments, the third width 405 is equal to the second width 142 and the first width 140. In further embodiments, the third width 405 is different from the first width 140 and the second width 142. In yet further embodiments, an area of each of the conductive bond pads in the first plurality of outer conductive bond pads 404 is equal to or approximately equal to (e.g., equal within a degree of error of about 5% or less) an area of each of the conductive bond pads in the first plurality of conductive bond pads 116 and the second plurality of conductive bond pads 118. In some embodiments, the third pitch P3 is less than about 15 um, within a range of about 0.75 to 15 um, less than about 10 um, within a range of about 0.75 to 10 um, or some other suitable value. In some embodiments, conductive bond pads 116, 118, 404 of the first bond structure 110 may, for example, each comprise a same material that may be copper, tungsten, titanium, tantalum, some other conductive material, or any combination of the foregoing. In further embodiments, conductive bond pads 116, 118, 404 of the first bond structure 110 may be referred to as conductive bond contacts, conductive bond elements, etc.

In various embodiments, a first ratio between the first pitch P1 and the second pitch P2 (e.g., P1:P2) is within a range of 0.15:5. In further embodiments, a second ratio between the second pitch P2 and the third pitch P3 (e.g., P2:P3) is within a range of 0.10:4.5. In some embodiments, the first ratio is greater than the second ratio. In some embodiments, the conductive bond pads 116, 118, 404 of the first bond structure 110 having the first ratio and the second ratio within the aforementioned ranges, mitigates a formation of non-bond regions between the first IC chip 102 and the second IC chip 104 and reduces fabrication complexity.

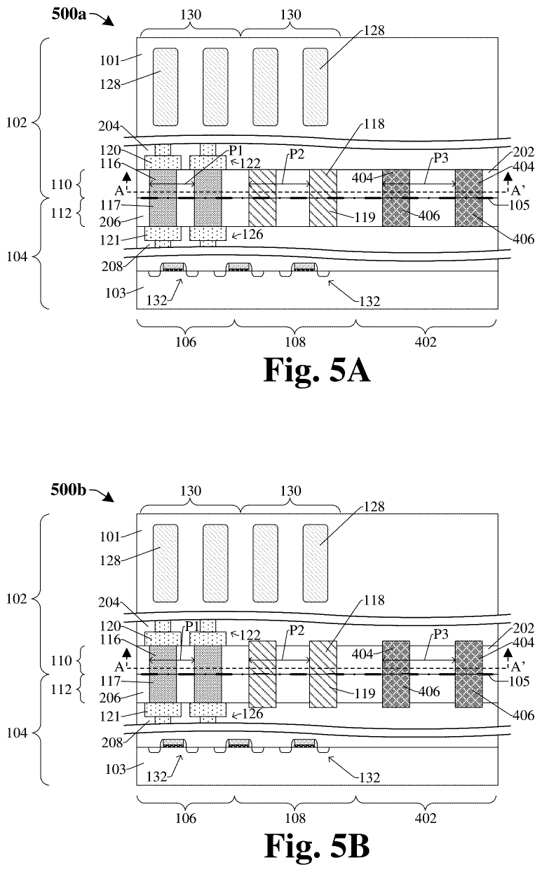

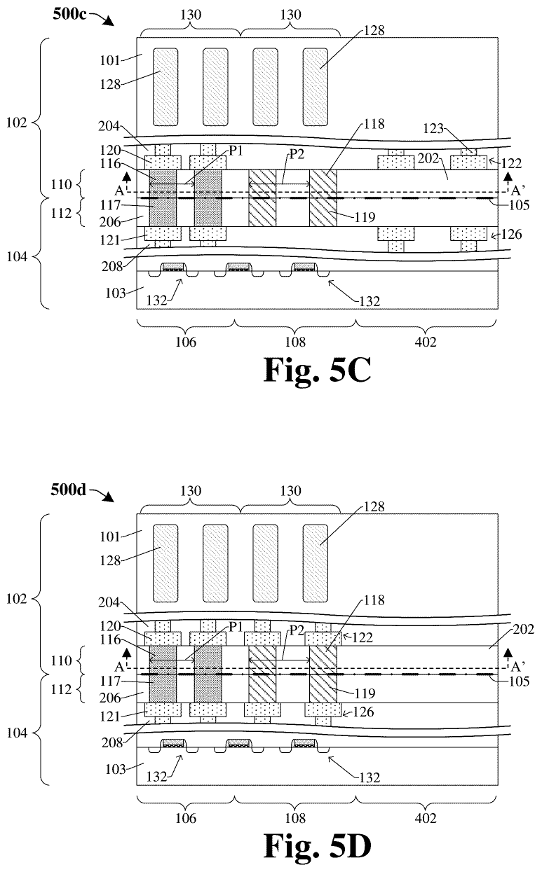

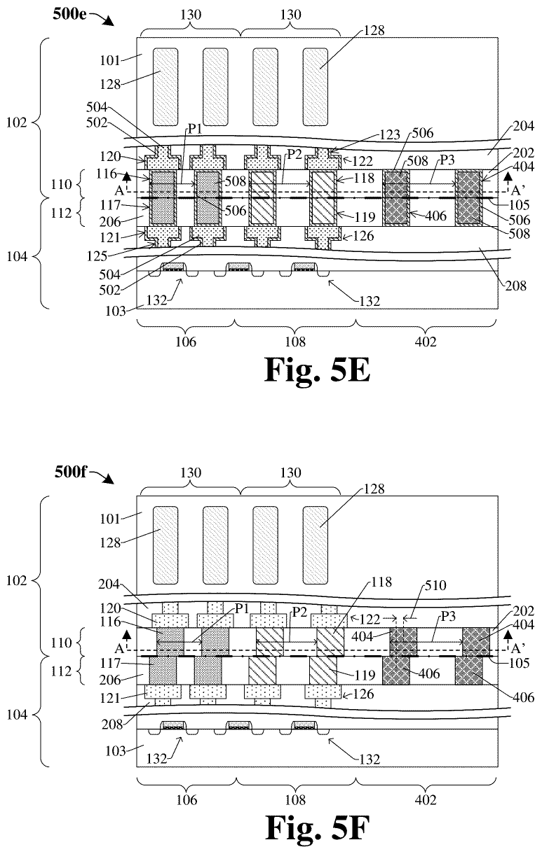

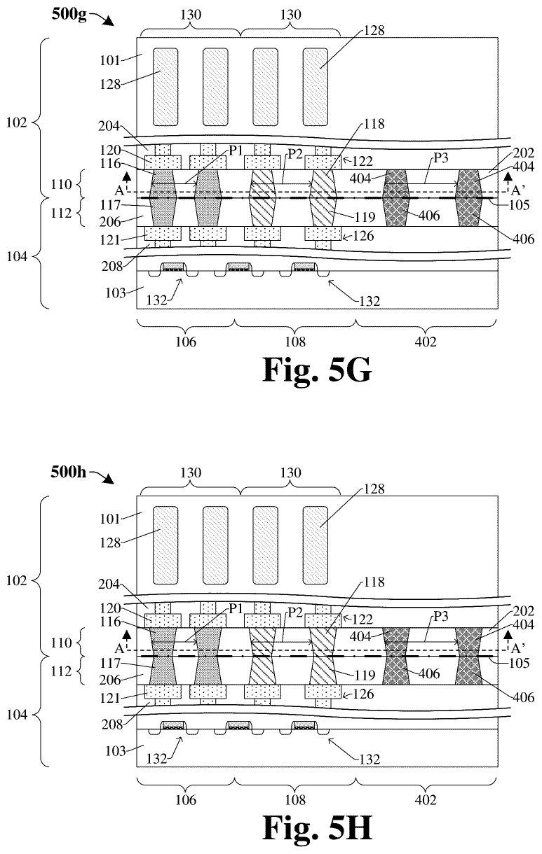

FIGS. 5A-5H illustrate various cross-sectional views 500a-500h of some other embodiments of the stacked IC device of FIGS. 4A and 4B. The FIGS. 5A-5H illustrate cross-sectional views 500a-h of some embodiments of the stacked IC device taken along the line A-A′ of FIG. 4A.

As illustrated in the cross-sectional view 500a of FIG. 5A, in some embodiments both the second plurality of conductive bond pads 118 and the first plurality of outer conductive bond pads 404 are configured as dummy conductive bond pads and are electrically floating.

As illustrated in the cross-sectional view 500b of FIG. 5B, in some embodiments lateral surfaces (e.g., top surfaces) of the second plurality of conductive bond pads 118 and the first plurality of outer conductive bond pads 404 extend above a bottom surface of the first interconnect dielectric 204.

As illustrated in the cross-sectional view 500c of FIG. 5C, the second plurality of conductive bond pads 118 are electrically floating. For example, the second plurality of conductive bond pads 118 are electrically isolated from conductive structures of the first interconnect structure 122. In further embodiments, the third region 402 is devoid of any conductive bond elements, such that a bottom surface of the first bond dielectric 202 continuously extends along and contacts a top surface of the second bond dielectric 206 along an entirety of an area of the third region 402. As a result, fabrication costs of the stacked IC device are decreased. In some embodiments, conductive wires 120 and/or conductive vias 123 of the first interconnect structure 122 are disposed in the third region 402.

As illustrated in the cross-sectional view 500d of FIG. 5D, the first plurality of outer conductive bond pads (404 of FIGS. 4A and 4B) are omitted from the third region 402. In various embodiments, the third region 402 is devoid of any conductive bond elements, such that a bottom surface of the first bond dielectric 202 continuously extends along and contacts a top surface of the second bond dielectric 206 along an entirety of an area of the third region 402. As a result, fabrication costs of the stacked IC device are decreased.

As illustrated in the cross-sectional view 500e of FIG. 5E, in some embodiments the first plurality of conductive wires and vias 120, 123 and the second plurality of conductive wires and vias 121, 125 each comprise a first liner layer 502 surrounding a first conductive body structure 504. The first liner layer 502 may, for example, be or comprise one or more of a diffusion barrier layer, an adhesion layer, a seed layer, or the like. The first liner layer 502 may, for example, be or comprise titanium nitride, tantalum nitride, some other conductive material, or any combination of the foregoing. The first conductive body structure 504 may, for example, be or comprise aluminum, copper, tungsten, ruthenium, some other conductive material, or any combination of the foregoing. In further embodiments, the conductive bond pads 116, 117, 118, 119, 404, 406 of the first and second bond structures 110, 112 respectively comprise a second liner layer 506 and a second conductive body structure 508. The second liner layer 506 may, for example, be or comprise one or more of a diffusion barrier layer, an adhesion layer, a seed layer, or the like. The second liner layer 506 may, for example, be or comprise titanium nitride, tantalum nitride, some other conductive material, or any combination of the foregoing. The second conductive body structure 508 may, for example, be or comprise aluminum, copper, tungsten, ruthenium, some other conductive material, or any combination of the foregoing.

As illustrated in the cross-sectional view 500f of FIG. 5F, in some embodiments, centers of the conductive bond pads 116, 118, 404 of the first bond structure 110 are respectively laterally offset from a center of a corresponding conductive bond pad in the conductive bond pads 117, 119, 406 of the second bond structure 112 by a lateral distance 510. The lateral distance 510 is non-zero. Centers of the conductive bond pads 116, 118, 404 of the first bond structure 110 may be laterally offset from centers of the conductive bond pads 117, 119, 406 of the second bond structure 112 during a bonding process performed on the first and second IC chips 102, 104.

As illustrated in the cross-sectional view 500g of FIG. 5G, in some embodiments, the conductive bond pads 116, 117, 118, 119, 404, 406 of the first and second bond structures 110, 112 respectively have a trapezoidal shape. In some embodiments, widths of the conductive bond pads 116, 118, 404 of the first bond structure 110 continuously decrease from a bottom surface of the first bond structure 110 in a first direction towards the first substrate 101. In further embodiments, widths of the conductive bond pads 117, 119, 406 of the second bond structure 112 continuously decrease from a top surface of the second bond structure 112 in a second direction towards the second substrate 103.

As illustrated in the cross-sectional view 500h of FIG. 5H, in some embodiments, the conductive bond pads 116, 117, 118, 119, 404, 406 of the first and second bond structures 110, 112 respectively have a trapezoidal shape. In some embodiments, widths of the conductive bond pads 116, 118, 404 of the first bond structure 110 continuously increase from a bottom surface of the first bond structure 110 in a first direction towards the first substrate 101. In further embodiments, widths of the conductive bond pads 117, 119, 406 of the second bond structure 112 continuously increase from a top surface of the second bond structure 112 in a second direction towards the second substrate 103.

It will be appreciated that the second bond structure 112 of the second IC chip 104 of FIGS. 1A-1B, 2A-2B, 3A-3B, 4A-4B, and 5A-5H may each be configured as and/or have a same layout as the first bond structure 110 of the first IC chip 102 of the corresponding figure. Thus, the first and second bond structures 110, 112 may have symmetrical layouts that facilitate a strong bond between the first and second IC chips 102, 104, thereby decreasing design complexity and increasing device yield.

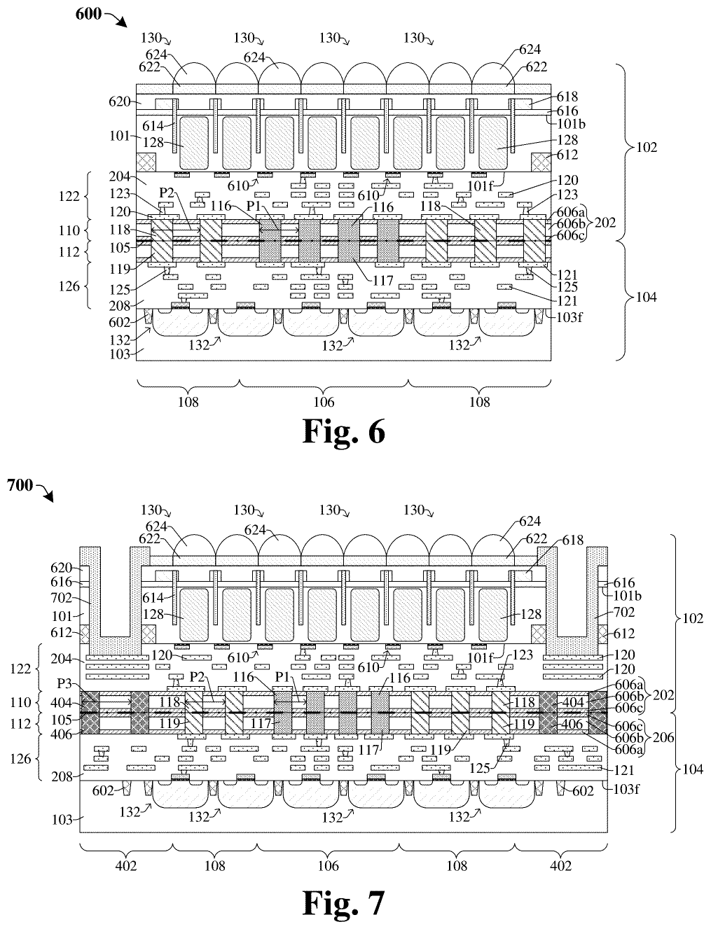

FIG. 6 illustrates a cross-sectional view 600 of some embodiments of a stacked IC device comprising a bond structure having first conductive bond pads arranged with a first pitch and second conductive bond pads arranged with a second pitch different from the first pitch.

The stacked IC device comprises a first IC chip 102 stacked on a second IC chip 104. The first IC chip 102 comprises a first substrate 101, a first interconnect structure 122 on the first substrate 101, and a first bond structure 110 on the first interconnect structure 122. The second IC chip 104 comprises a second substrate 103, a second interconnect structure 126 on the second substrate 103, and a second bond structure 112 on the second interconnect structure 126. The first substrate 101 and the second substrate 103 may, for example, each be or comprise silicon, a silicon wafer, monocrystalline silicon, CMOS bulk, silicon-germanium, one or more epitaxial layers (e.g., epitaxial silicon layers), a silicon-on-insulator (SOI) substrate, or some other type of semiconductor substrate.

In some embodiments, the second IC chip 104 is configured as an application-specific integrated circuit (ASIC) or another suitable device. A plurality of semiconductor devices 132 are disposed on a front-side surface 103f of the second substrate 103. The plurality of semiconductor devices 132 may, for example, be configured as logic devices, transistors, or some other suitable device. In various embodiments, the plurality of semiconductor devices 132 each comprise a gate electrode over a gate dielectric, a plurality of source/drain regions disposed on opposing sides of the gate electrode, and a well region in the second substrate 103. A shallow trench isolation (STI) structure 602 is disposed in the second substrate 103 and is configured to electrically isolate the semiconductor devices 132 from one another. The second interconnect structure 126 is configured to electrically couple the semiconductor devices 132 to one another and/or to devices of the second IC chip 104.

The first interconnect structure 122 comprises a first plurality of conductive wires 120 and a first plurality of conductive vias 123 disposed in a first interconnect dielectric 204. The second interconnect structure 126 comprises a second plurality of conductive wires 121 and a second plurality of conductive vias 125 disposed in a second interconnect dielectric 208. The first and second interconnect dielectrics 204, 208 may each comprise a plurality of dielectric layers vertically stacked with one another that may, for example, be or comprise silicon dioxide, a low-k dielectric material, an extreme low-k dielectric material, silicon nitride, silicon carbide, or the like. The conductive wires 120, 121 and the conductive vias 123, 125 may, for example, be or comprise aluminum, titanium nitride, tantalum nitride, tungsten, ruthenium, some other conductive material, or any combination of the foregoing.

In some embodiments, the first IC chip 102 is configured as a CMOS imaging chip comprising a plurality of pixels 130. In various embodiments, the first IC chip 102 is configured as a system-on-chip (SoC). In further embodiments, the first IC chip 102 comprises one or more of a central processing unit (CPU), one or more memory devices, a graphics processing unit (GPU), a digital signal processor (DSP), or some other suitable electronic device. The first IC chip 102 comprises a plurality of photodetectors 128 disposed in in the first substrate 101. A plurality of pixel devices 610 are disposed on the first substrate. The plurality of pixel devices 610 may, for example, be configured as and/or include transfer transistors, reset transistors, select transistors, source-follower transistors, etc. The pixels 130 each comprise one or more of the photodetectors 128 and one or more of the pixel devices 610.

The photodetectors 128 are configured to absorb incident light (e.g., photons) and generate respective electrical signals corresponding to the incident light. For example, the photodetectors 128 may generate electron-hole pairs from the incident light. At least a subset of the pixel devices 610 (e.g., the pixel devices configured as transfer transistors) are configured to control current flow between the photodetectors 128 and a corresponding floating diffusion node (not shown) in the first substrate 101. The pixel devices 610 are configured to facilitate readout of electrical signals from the plurality of pixels 130 that correspond to incident light received at the photodetectors 128.

A shallow trench isolation (STI) structure 612 is disposed in the first substrate 101. An isolation structure 614 extends into a back-side surface 101b of the first substrate 101. The isolation structure 614 is disposed between adjacent photodetectors in the plurality of photodetectors 128. In various embodiments, the isolation structure 614 continuously laterally extends around each of the photodetectors in the plurality of photodetectors 128. The isolation structure 614 increases electrical isolation between the pixels 130 and increases optical isolation between the photodetectors 128. The isolation structure 614 may, for example, be or comprise one or more layers comprising a conductive material (e.g., aluminum, copper, tungsten, etc.), a dielectric material (e.g., silicon dioxide, aluminum oxide, silicon nitride, etc.), or some other suitable material. An upper dielectric layer 616 is disposed on the back-side surface 101b of the first substrate 101. The upper dielectric layer 616 may, for example, be or comprise silicon dioxide, silicon nitride, silicon carbide, or the like. A grid structure 618 overlies the back-side surface 101b of the first substrate 101 and comprises a plurality of opposing sidewalls defining a plurality of openings over the photodetectors 128. The grid structure 618 is configured to decrease cross-talk between adjacent photodetectors 128, thereby increasing optical isolation.

An upper dielectric structure 620 overlies the grid structure 618 and fills the openings defined by the opposing sidewalls of the grid structure 618. The upper dielectric structure 620 may, for example, be or comprise an oxide (e.g., silicon dioxide) or some other suitable dielectric material. A plurality of light filters 622 are disposed over the plurality of photodetectors 128. The plurality of light filters 622 each comprise a material configured to pass a first range of wavelengths while blocking a second range of wavelengths different from the first range of wavelengths. A plurality of micro-lenses 624 overlie the light filters 622 and are configured to direct incident light towards the photodetectors 128.

In various embodiments, the first bond structure 110 comprises a first plurality of conductive bond pads 116 arranged in the first region 106 with a first pitch P1, a second plurality of conductive bond pads 118 arranged in the second region 108 with a second pitch P2 greater than the first pitch P1, and a first bond dielectric 202. The first plurality of conductive bond pads 116 and the second plurality of conductive bond pads 118 are disposed in the first bond dielectric 202. The first bond dielectric 202 comprises a first dielectric layer 606a, a second dielectric layer 606b, and a third dielectric layer 606c. The second bond structure 112 comprises a third plurality of conductive bond pads 117 arranged in the first region 106 with the first pitch P1 and a fourth plurality of conductive bond pads 119 arranged in the second region 108 with the second pitch P2. The first and second bond structures 110, 112 meet one another at the bond interface 105 that comprises conductor-to-conductor bonds and dielectric-to-dielectric bonds. In various embodiments, the first and second bond structures 110, 112 comprising the conductive bond pads with varying pitches decreases a complexity of routing electrical signals between the first and second IC chips 102, 104. This, in part, facilitates scaling features of the pixels 130, thereby increasing a device density of the stacked IC device and a resolution and/or quality of images generated from the stacked IC device. Further, the second pitch P2 being greater than the first pitch P1 mitigates non-bond regions between the first and second IC chips 102, 104, thereby increasing an overall performance and yield of the stacked IC device.

In some embodiments, conductive bond pads 116, 117, 118, 119 of the first and second bond structures 110, 112 may, for example, respectively comprise copper, tungsten, titanium, tantalum, some other conductive material, or any combination of the foregoing. In further embodiments, the first bond structure 110 and the second bond structure 112 each comprise a single layer of conductive bond elements, thereby reducing a number of conductive structures in the first and second IC chips 102, 104. Accordingly, fabrication costs are reduced. The first dielectric layer 606a may, for example, be or comprise silicon nitride, silicon carbide, or some other suitable dielectric material. The second dielectric layer 606b may, for example, be or comprise an oxide (e.g., silicon dioxide) or some other suitable dielectric material. The third dielectric layer 606c may, for example, be or comprise silicon oxynitride, silicon oxycarbide, or some other suitable dielectric material.

FIG. 7 illustrates a cross-sectional view 700 of some other embodiments of the stacked IC device of FIG. 6, where the first bond structure 110 further comprises a first plurality of outer conductive bond pads 404 disposed in a third region 402 adjacent to the second region 108. In some embodiments, the first and second bond structures 110, 112 may be configured as illustrated and/or described in any of FIGS. 4A, 4B, and 5A-5D.

In some embodiments, the first IC chip 102 further comprises a plurality of upper bond elements 702 extending through the first substrate 101 to one or more conductive structures in the first interconnect structure 122. The upper bond elements 702 are configured to electrically couple the stacked IC device to another electronic device (not shown). The first plurality of outer conductive bond pads 404 are disposed outside of the plurality of photodetectors 128. In various embodiments, the plurality of upper bond elements 702 are spaced in the third region 402 and directly overlie the plurality of outer conductive bond pads 404.

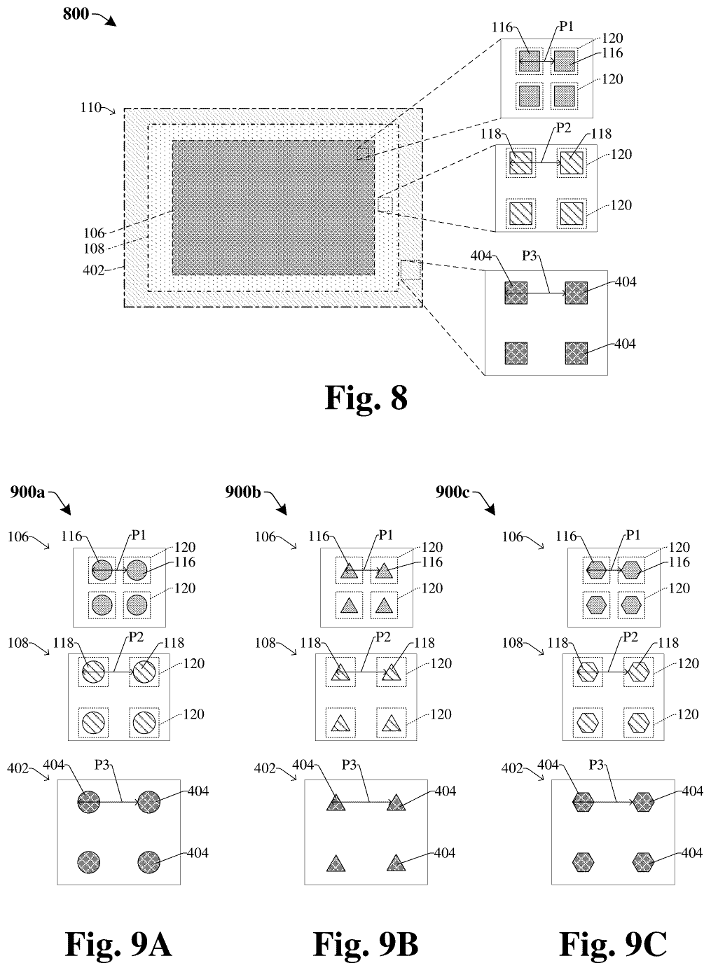

FIG. 8 illustrates a top view 800 of some other embodiments of the first bond structure of FIG. 4A. The first bond structure 110 comprises the first plurality of conductive bond pads 116 arranged in the first region 106 with the first pitch P1, the second plurality of conductive bond pads 118 arranged in the second region 108 with the second pitch P2, and the first plurality of outer conductive bond pads 404 arranged in the third region 402 with the third pitch P3.

In some embodiments, the first plurality of conductive bond pads 116 are arranged in the first region 106 with a first density, the second plurality of conductive bond pads 118 are arranged in the second region 108 with a second density less than the first density, and the first plurality of outer conductive bond pads 404 are arranged in the third region 402 with a third density less than the second density. In various embodiments, an area of the first region 106 is greater than an area of the second region 108, and an area of the third region 402 is less than the area of the second region 108.

FIGS. 9A-9C illustrate various top views 900a-900c of some embodiments of the conductive bond pads in the first, second, and third regions of FIG. 8.

As illustrated in the top view 900a of FIG. 9A, conductive bond pads in the first plurality of conductive bond pads 116, the second plurality of conductive bond pads 118, and the first plurality of outer conductive bond pads 404 each have a circular shape when viewed from above.

As illustrated in the top view 900b of FIG. 9B, conductive bond pads in the first plurality of conductive bond pads 116, the second plurality of conductive bond pads 118, and the first plurality of outer conductive bond pads 404 each have a triangular shape when viewed from above.

As illustrated in the top view 900c of FIG. 9C, conductive bond pads in the first plurality of conductive bond pads 116, the second plurality of conductive bond pads 118, and the first plurality of outer conductive bond pads 404 each have a polygon shape (e.g., a hexagon shape, pentagon shape, etc.) when viewed from above.

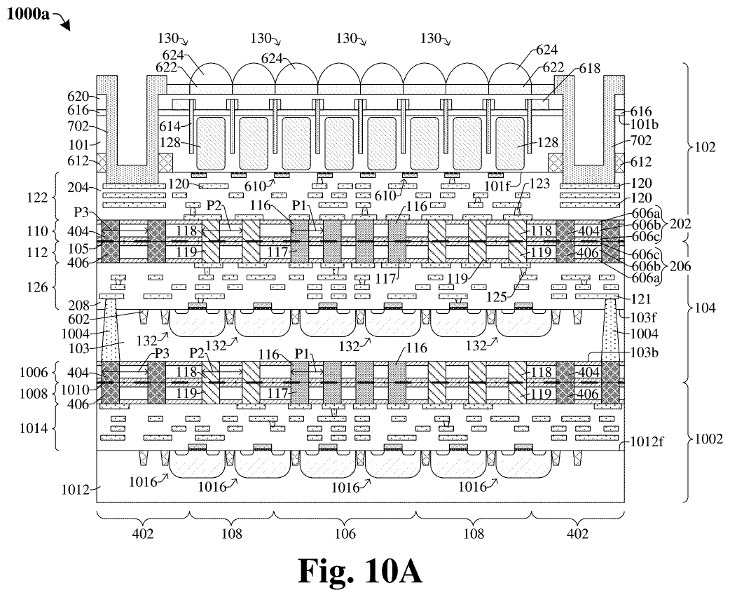

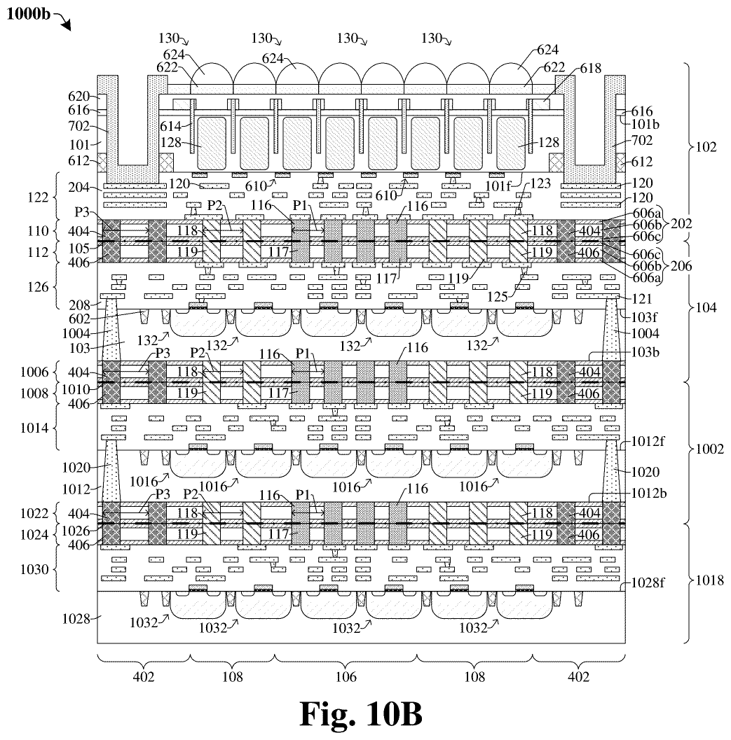

FIG. 10A illustrates a cross-sectional view 1000a of some embodiments of a stacked IC device comprising a first IC chip, a second IC chip, and a third IC chip that each comprise one or more bond structures having conductive bond pads with varying pitches.

In some embodiments, the stacked IC device comprises the first IC chip 102, the second IC chip 104, and a third IC chip 1002. The second IC chip 104 is disposed between the first IC chip 102 and the third IC chip 1002. In some embodiments, the second IC chip 104 further comprises a third bond structure 1006 disposed on a back-side surface 103b of the second substrate 103. In various embodiments, a lower interconnect structure (not shown) is disposed between the back-side surface 103b of the second substrate 103 and the third bond structure 1006. In such embodiments, the lower interconnect structure is configured to route electrical connections between the third bond structure 1006 and overlying structures (e.g., the second interconnect structure 126 and/or the first IC chip 102). Further, a first plurality of through substrate vias (TSVs) 1004 are disposed in the second substrate 103 and are configured to electrically couple the third IC chip 1002 to the second interconnect structure 126. In various embodiments, the first plurality of TSVs 1004 are spaced laterally within the third region 402.

The third IC chip 1002 comprises a third substrate 1012, a third interconnect structure 1014 on a front-side surface 1012f of the third substrate 1012, and a fourth bond structure 1008 on the third interconnect structure 1014. The third interconnect structure 1014 comprises a plurality of conductive wires (not labeled) and a plurality of conductive vias (not labeled). Further, a second plurality of semiconductor devices 1016 (e.g., transistors) are disposed on the third substrate 1012. A second bond interface 1010 is disposed between the third IC chip 1002 and the second IC chip 104. In various embodiments, the third bond structure 1006 is configured as the first bond structure 110 and the fourth bond structure 1008 is configured as the second bond structure 112 (e.g., as illustrated and/or described in any of FIGS. 1A-1B, 2A-2B, 3A-3B, 4A-4B, and 5A-5D). Accordingly, the third and fourth bond structures 1006, 1008 respectively comprise conductive bond pads arranged with varying pitches across the regions 106, 108, 402, thereby mitigating or preventing non-bond regions between the second and third IC chips 104, 1002. As a result, an overall performance and yield of the stacked IC device are increased. In various embodiments, outer conductive bond pads 404, 406 in the third and fourth bond structures 1006, 1008 are electrically coupled to conductive features in the second and/or third IC chips 104, 1002 (e.g., coupled to the TSVs 1004 and/or conductive elements in the third interconnect structure 1014).

FIG. 10B illustrates a cross-sectional view 1000b of some other embodiments of the stacked IC device of FIG. 10A, where the stacked IC device further includes a fourth IC chip under the third IC chip.

In some embodiments, the stacked IC device comprises the first IC chip 102, the second IC chip 104, the third IC chip 1002, and a fourth IC chip 1018. In some embodiments, the third IC chip 1002 further comprises a fifth bond structure 1022 disposed on a back-side surface 1012b of the third substrate 1012. In various embodiments, a second lower interconnect structure (not shown) is disposed between the back-side surface 1012b and the fifth bond structure 1022. A second plurality of TSVs 1020 are disposed in the third substrate 1012 and are configured to electrically couple the fourth IC chip 1018 to the third interconnect structure 1014.

The fourth IC chip 1018 comprises a fourth substrate 1028, a fourth interconnect structure 1030 on a front-side surface 1028f of the fourth substrate 1028, and a sixth bond structure 1024 on the fourth interconnect structure 1030. The fourth interconnect structure 1030 comprises a plurality of conductive wires (not labeled) and a plurality of conductive vias (not labeled). Further, a third plurality of semiconductor devices 1032 (e.g., transistors) are disposed on the fourth substrate 1028. A third bond interface 1026 is disposed between the third IC chip 1002 and the fourth IC chip 1018. In some embodiments, the fifth bond structure 1022 is configured as the first bond structure 110 and the sixth bond structure 1024 is configured as the second bond structure 112 (e.g., as illustrated and/or described in any of FIGS. 1A-1B, 2A-2B, 3A-3B, 4A-4B, and 5A-5D). Accordingly, the fifth and sixth bond structures 1022, 1024 respectively comprise conductive bond pads arranged with varying pitches across the regions 106, 108, 402, thereby mitigating or preventing non-bond regions between the second and third IC chips 104, 1002 and increasing an overall performance of the stacked IC device. In various embodiments, outer conductive bond pads 404, 406 in the fifth and sixth bond structures 1022, 1024 are electrically coupled to conductive features in the third and/or fourth IC chips 1002, 1018 (e.g., coupled to the TSVs 1004 and/or conductive elements in the third interconnect structure 1014).

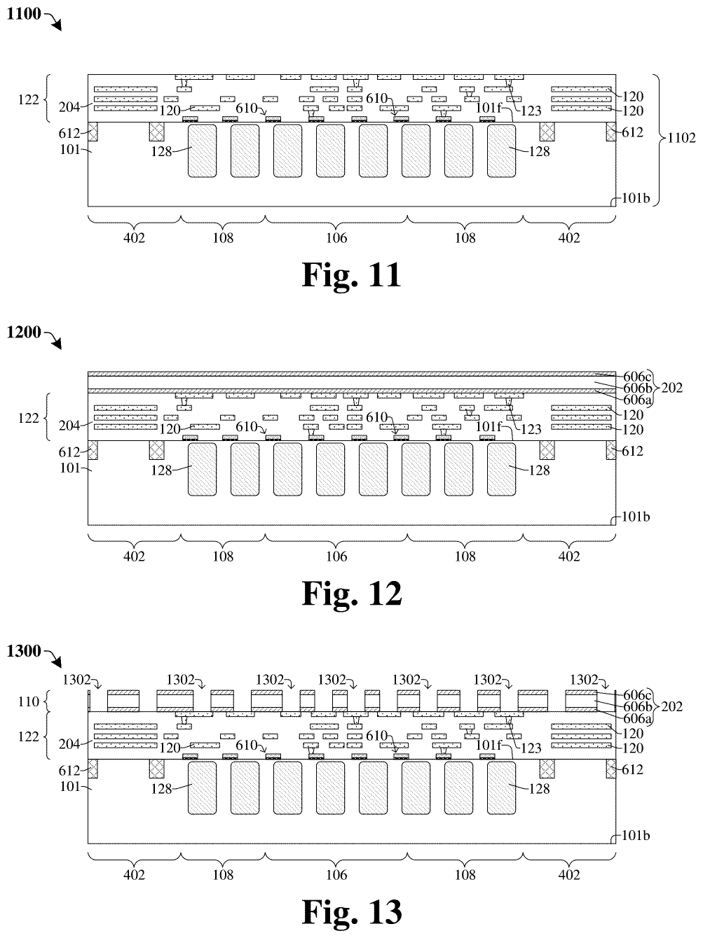

FIGS. 11-19 illustrate various cross-sectional views 1100-1900 of some embodiments of a method of forming a stacked IC device comprising bond structures having conductive bond pads with varying pitches disposed across multiple regions. Although the cross-sectional views 1100-1900 shown in FIGS. 11-19 are described with reference to the method, it will be appreciated that the structures shown in FIGS. 11-19 are not limited to the method but rather may stand alone separate of the method. Furthermore, although FIGS. 11-19 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 1100 of FIG. 11, a first IC structure 1102 is provided or otherwise formed. The first IC structure 1102 includes a first substrate 101, a plurality of photodetectors 128 disposed in the first substrate 101, a plurality of pixel devices 610 on the first substrate 101, and a first interconnect structure 122 on a front-side surface 101f of the first substrate 101. A shallow trench isolation (STI) structure 612 is disposed in the first substrate 101. The first interconnect structure 122 comprises a first plurality of conductive wires 120 and a first plurality of conductive vias 123 disposed in a first interconnect dielectric 204.

In some embodiments, the plurality of photodetectors 128 are formed in the first substrate 101 by an ion implantation process. The plurality of pixel devices 610 may be formed on the first substrate 101 by one or more deposition process(es), one or more ion implantation process(es), one or more patterning process(es), one or more planarization process(es), some other suitable fabrication process(es), or any combination of the foregoing. The first plurality of conductive wires 120 and the first plurality of conductive vias 123 may, for example, be formed by one or more single damascene process(es), dual damascene process(es), or some other suitable fabrication process(es).

As shown in cross-sectional view 1200 of FIG. 12, a first bond dielectric 202 is formed on the first interconnect structure 122. In some embodiments, the first bond dielectric 202 comprises a first dielectric layer 606a, a second dielectric layer 606b, and a third dielectric layer 606c. Layers of the first bond dielectric 202 may each be formed by an individual deposition process, such as a chemical vapor deposition (CVD) process, a physical vapor deposition (PVD) process, an atomic layer deposition (ALD) process, or some other suitable growth or deposition process.

The first dielectric layer 606a may be configured as an etch stop layer and may, for example, be or comprise, silicon nitride, silicon carbide, some other dielectric material, or any combination of the foregoing. In some embodiments, the first dielectric layer 606a is formed to a thickness of about 1,200 angstroms, within a range of about 1,000 to 1,400 angstroms, or some other suitable value. The second dielectric layer 606b may, for example, be or comprise an oxide such as silicon dioxide or some other dielectric material and may be formed to a thickness of about 4,000 angstroms, within a range of about 3,500 to 4,500 angstroms, or some other suitable value. The third dielectric layer 606c may, for example, be or comprise silicon oxynitride, silicon oxycarbide, some other dielectric material, or any combination of the foregoing and may be formed to a thickness of about 850 angstroms, within a range of about 700 to 1,000 angstroms, or some other suitable value.

As shown in cross-sectional view 1300 of FIG. 13, a patterning process is performed on the first bond dielectric 202 to form a plurality of openings 1302 in the first bond dielectric 202. In some embodiments, the patterning process includes: forming a masking layer (not shown) on the first bond dielectric 202; performing an etching process (e.g., a dry etch process) on the first bond dielectric 202 according to the masking layer; and performing a removal process to remove the masking layer.

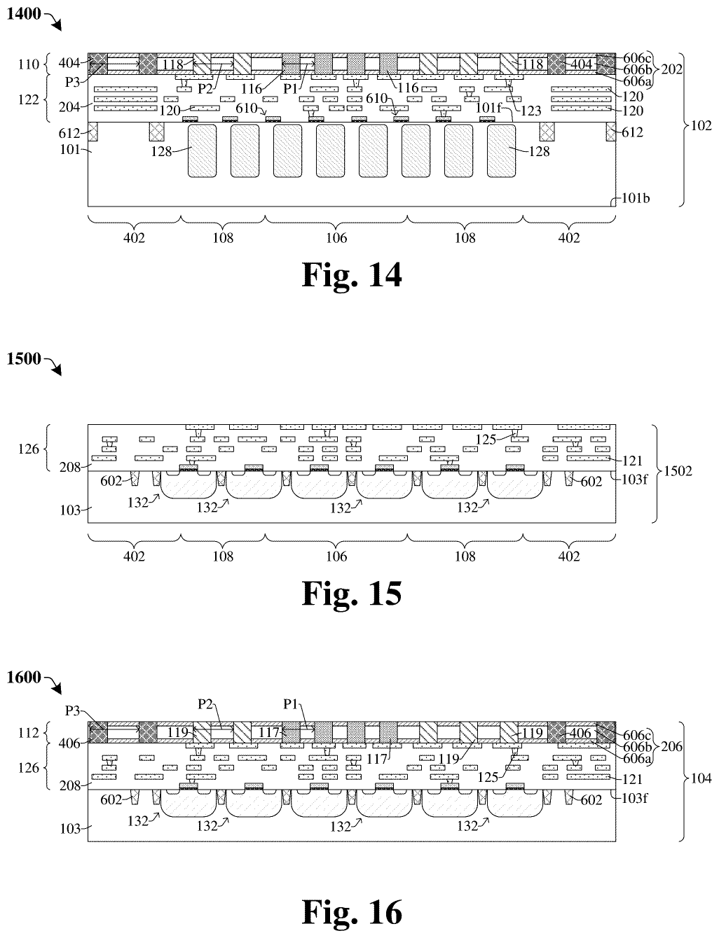

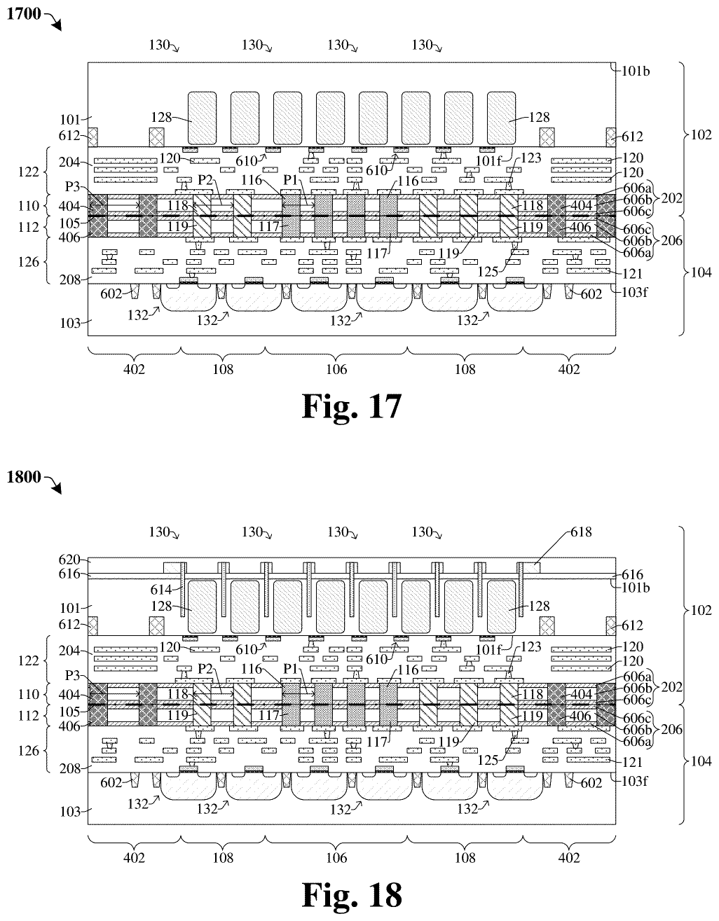

As shown in cross-sectional view 1400 of FIG. 14, a first plurality of conductive bond pads 116, a second plurality of conductive bond pads 118, and a first plurality of outer conductive bond pads 404 are formed in the first bond dielectric 202, thereby forming or defining a first bond structure 110 on the first interconnect structure 122 and defining a first IC chip 102. In various embodiments, a process for forming the conductive bond pads 116, 118, 404 of the first bond structure 110 includes: depositing (e.g., by CVD, PVD, sputtering, electroplating, electroless plating, etc.) a conductive material (e.g., copper, aluminum, tungsten, etc.) over the first bond dielectric 202 and in the plurality of openings (1302 of FIG. 13) and performing a planarization process (e.g., a chemical mechanical planarization (CMP) process) on the conductive material. In some embodiments, after the planarization process, a top surface of the first bond dielectric 202 and top surfaces of the conductive bond pads 116, 118, 404 are coplanar and substantially flat, thereby mitigating a formation of non-bond areas in a subsequent bonding process (e.g., the bonding process of FIG. 17). In various embodiments, a process for forming the first bond structure 110 includes the processing steps illustrated and/or described in FIGS. 12-14.

In some embodiments, the first plurality of conductive bond pads 116 are formed in a first region 106 with a first pitch P1, the second plurality of conductive bond pads 118 are formed in a second region 108 with a second pitch P2, and the first plurality of outer conductive bond pads 404 are formed in a third region 402 with a third pitch P3. In some embodiments, the first pitch P1 is less than the second pitch P2 and the second pitch P2 is less than the third pitch P3. Accordingly, a first density of conductive bond pads in the first region 106 is greater than a second density of conductive bond pads in the second region 108, and the second density is greater than a third density of conductive bond pads in the third region 402. The density of conductive bond pads decreasing from the first region 106 to the third region 402 mitigates issues (e.g., reduced removal of materials in outer regions of the first IC chip 102) due to limitations in processing tools utilized to perform the planarization process. As a result, a top surface of the first bond structure 110 is substantially flat and/or a TTV of the first IC chip 102 is relatively low, thereby mitigating the formation of non-bond areas in the subsequent bonding process. It will be appreciated that while the first bond structure 110 is illustrated as being formed as the first bond structure 110 of FIGS. 4A-4B, the first bond structure 110 may be formed to be configured as the first bond structure 110 of any of FIGS. 1A-1B, 2A-2B, 3A-3B, 5A-5D, 6, 8, and 9A-9C.

In various embodiments, the patterning process of FIG. 13 may include: performing a first patterning process to define a first subset of the openings (1302 of FIG. 13) in the first region 106 with the first pitch P1; performing a second patterning process to define a second subset of the openings (1302 of FIG. 13) in the second region 108 with the second pitch P2; and performing a third patterning process to define a third subset of the openings (1302 of FIG. 13) in the third region 402 with the third pitch P3. In some embodiments, each of the first, second, and third patterning processes are performed according to different masking layers (not shown). For instance, the first patterning process is performed according to a first masking layer, the second patterning process is performed according to a second masking layer, and so on.

As shown in cross-sectional view 1500 of FIG. 15, a second IC structure 1502 is provided or otherwise formed. The second IC structure 1502 includes a second substrate 103, a plurality of semiconductor devices 132 on the second substrate 103, and a second interconnect structure 126 on a front-side surface 103f of the second substrate 103. An STI structure 602 is disposed in the second substrate 103. The second interconnect structure 126 comprises a second plurality of conductive wires 121 and a second plurality of conductive vias 123 disposed in a second interconnect dielectric 208.

The plurality of semiconductor devices 132 may be formed on the second substrate 103 by one or more deposition process(s), one or more ion implantation process(es), one or more patterning process(s), one or more planarization process(es), some other suitable fabrication process(es), or any combination of the foregoing. The second plurality of conductive wires 121 and the second plurality of conductive vias 125 may, for example, be formed by one or more single damascene process(es), dual damascene process(es), or some other suitable fabrication process(es).

As shown in cross-sectional view 1600 of FIG. 16, a second bond structure 112 is formed on the second interconnect structure 126, thereby defining a second IC chip 104. In various embodiments, the second bond structure 112 comprises a third plurality of conductive bond pads 117 arranged with the first pitch P1, a fourth plurality of conductive bond pads 119 arranged with the second pitch P2, and a second plurality of outer conductive bond pads 406 arranged with the third pitch P3. In various embodiments, the second bond structure 112 is formed by the processing steps illustrated and/or described in FIGS. 12-14 for forming the first bond structure (110 of FIG. 14).

As shown in cross-sectional view 1700 of FIG. 17, the first IC chip 102 is flipped and bonded to the second IC chip 104 such that a bond interface 105 is disposed between the first bond structure 110 and the second bond structure 112. In various embodiments, bonding the first IC chip 102 to the second IC chip 104 includes: aligning the first IC chip 102 with the second IC chip 104, bringing the first bond structure 110 in contact with the second bond structure 113, and applying pressure to the first IC chip 102 and/or the second IC chip 104. In some embodiments, temperatures of the first and second bond structures 110, 112 may be increased to form the bond interface 105. By virtue of the first bond structure 110 and the second bond structure 112 being formed with the varying conductive bond pad densities as illustrated and/or described in FIG. 14, the formation of non-bond areas between the first and second IC chips 102, 104 is mitigated, thereby increasing a yield of the stacked IC device.

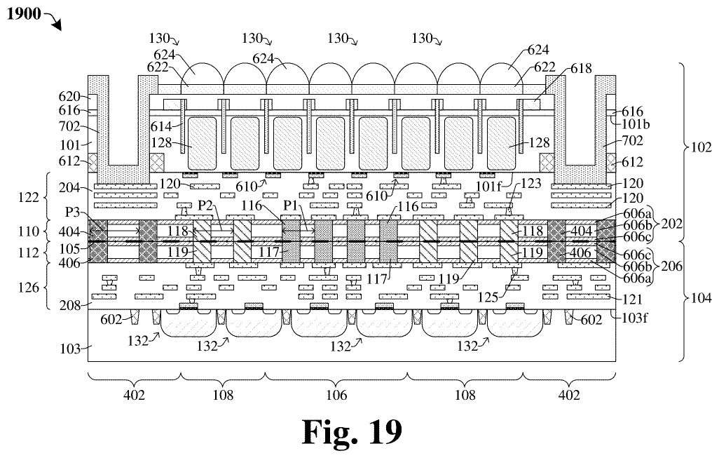

As shown in cross-sectional view 1800 of FIG. 18, a thinning process is performed on the first substrate 101 and an isolation structure 614 is formed in the first substrate 101. In some embodiments, the thinning process reduces a thickness of the first substrate 101 and includes performing a mechanical grinding process, a CMP process, or the like. An upper dielectric layer 616 is formed on the back-side surface 101b of the first substrate 101. A grid structure 618 is formed on the upper dielectric layer 616. The isolation structure 614 is formed extending through the first substrate 101 and is disposed between adjacent photodetectors in the plurality of photodetectors 128. Further, an upper dielectric structure 620 is formed over the grid structure 618.

As shown in cross-sectional view 1900 of FIG. 19, a plurality of upper bond elements 702 are formed extending through the first substrate 101 to a corresponding conductive structure in the first interconnect structure 122. In some embodiments, forming the plurality of upper bond elements 702 includes: patterning the back-side surface 101b of the first substrate 101 to form bond element openings extending to the first interconnect structure 122; depositing a conductive layer in the bond element openings; and performing an etching process on the conductive layer. Further, a plurality of light filters 622 are formed over the photodetectors 128 and a plurality of micro-lenses 624 are formed on the plurality of light filters 622. The plurality of light filters 622 may, for example, be formed by depositing and patterning respective light filter layers corresponding to the plurality of light filters 622. The micro-lenses 624 may, for example, be formed by depositing a micro-lens material over the light filters 622 and patterning the micro-lens material to form the plurality of micro-lenses 624.

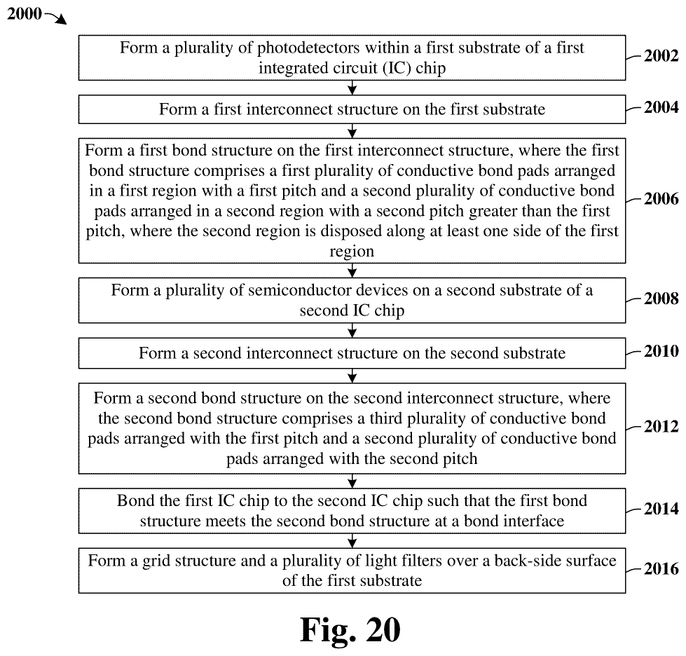

FIG. 20 illustrates some embodiments of a method 2000 of forming a stacked IC device comprising bond structures having conductive bond pads with varying pitches disposed across multiple regions. Although the method 2000 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2002, a plurality of photodetectors are formed within a first substrate of a first IC chip. FIG. 11 illustrates a cross-sectional view 1100 corresponding to some embodiments of act 2002.

At act 2004, a first interconnect structure is formed on the first substrate. FIG. 11 illustrates the cross-sectional view 1100 corresponding to some embodiments of act 2004.

At act 2006, a first bond structure is formed on the first interconnect structure. The first bond structure comprises a first plurality of conductive bond pads arranged in a first region with a first pitch and a second plurality of conductive bond pads arranged in a second region with a second pitch greater than the first pitch, where the second region is disposed along at least one side of the first region. FIGS. 12-14 illustrate cross-sectional views 1200-1400 corresponding to some embodiments of act 2006.

At act 2008, a plurality of semiconductor devices are formed on a second substrate of a second IC chip. FIG. 15 illustrates a cross-sectional view 1500 corresponding to some embodiments of act 2008.

At act 2010, a second interconnect structure is formed on the second substrate. FIG. 15 illustrates the cross-sectional view 1500 corresponding to some embodiments of act 2010.

At act 2012, a second bond structure is formed on the second interconnect structure. The second bond structure comprises a third plurality of conductive bond pads arranged with the first pitch and a second plurality of conductive bond pads arranged with the second pitch. FIG. 16 illustrates a cross-sectional view 1600 corresponding to some embodiments of act 2012.

At act 2014, the first IC chip is bonded to the second IC chip such that the first bond structure meets the second bond structure at a bond interface. FIG. 17 illustrates a cross-sectional view 1700 corresponding to some embodiments of act 2014.

At act 2016, a grid structure and a plurality of light filters are formed over a back-side surface of the first substrate. FIGS. 18 and 19 illustrate cross-sectional views 1800 and 1900 corresponding to some embodiments of act 2016.

Accordingly, in some embodiments, the present disclosure relates to a stacked IC device comprising a first IC chip bonded to a second IC chip, where the first and second IC chips comprise bond structures that respectively comprise a first plurality of conductive bond pads arranged with a first pitch and a second plurality of conductive bond pads arranged with a second pitch greater than the first pitch.

In some embodiments, the present application provides a device that includes: an interconnect structure on a substrate; a bond structure over the interconnect structure, wherein the bond structure comprises: a first plurality of conductive bond pads disposed in a first region; and a second plurality of conductive bond pads disposed in a second region, wherein the second region is adjacent to at least one side of the first region, wherein a first pitch of the first plurality of conductive bond pads is less than a second pitch of the second plurality of conductive bond pads. In an embodiment, the first plurality of conductive bond pads are arranged in an array comprising a plurality of columns and a plurality of rows. In an embodiment, the second plurality of conductive bond pads are arranged in one or more rows and/or one or more columns, wherein a first density of the first plurality of conductive bond pads is greater than a second density of the second plurality of conductive bond pads. In an embodiment, the first plurality of conductive bond pads contact corresponding first conductive wires in the interconnect structure. In an embodiment, the second plurality of conductive bond pads contact corresponding second conductive wires in the interconnect structure. In an embodiment, the second plurality of conductive bond pads are electrically floating, wherein top surfaces of the second plurality of conductive bond pads are offset from conductive structures in the interconnect structure by non-zero distances. In an embodiment, the device further includes a plurality of photodetectors disposed in the substrate, wherein the first region directly underlies the plurality of photodetectors. In an embodiment, the substrate further comprises a third region laterally offset from the plurality of photodetectors, wherein the second region is arranged between the first region and the third region, wherein the bond structure further comprises a third plurality of conductive bond pads in the third region, wherein a third pitch of the third plurality of conductive bond pads is greater than or equal to the second pitch. In an embodiment, the substrate further comprises a third region laterally offset from the plurality of photodetectors, wherein the second region is arranged between the first region and the third region, wherein the bond structure is devoid of conductive bond structures in the third region.

In further embodiments, the present application provides a package including a first integrated circuit (IC) chip comprising a first substrate, a first interconnect structure, and a first bond structure, wherein the first bond structure comprises a first plurality of conductive bond pads disposed in a first region of the first substrate and a second plurality of conductive bond pads disposed in a second region of the first substrate, wherein the second region is disposed between the first region and an outer edge of the first IC chip; a second IC chip comprising a second substrate under the first IC chip, a second interconnect structure, and a second bond structure; and wherein an interface is disposed between the first bond structure and the second bond structure, wherein a first density of the first plurality of conductive bond pads is greater than a second density of the second plurality of conductive bond pads. In an embodiment, the first plurality of conductive bond pads are arranged in the first region with a uniform pitch and the second plurality of conductive bond pads are arranged in the second region with a nonuniform pitch, wherein a minimum pitch of the nonuniform pitch is greater than the uniform pitch. In an embodiment, the first bond structure comprises a single level of conductive elements comprising the first plurality of conductive bond pads and the second plurality of conductive bond pads, wherein bottom surfaces of the first plurality of conductive bond pads are substantially coplanar with bottom surfaces of the second plurality of conductive bond pads. In an embodiment, the first bond structure comprises a first plurality of dummy conductive bond pads disposed in a third region of the first substrate, wherein the second region is spaced between the third region and the second region, wherein a third density of the first plurality of dummy conductive bond pads is less than the second density. In an embodiment, the second bond structure comprises a third plurality of conductive bond pads in the first region with the first density, a fourth plurality of conductive bond pads in the second region with the second density, and a second plurality of dummy conductive bond pads in the third region with the third density. In an embodiment, a first number of conductive bond pads in the first region is greater than a second number of conductive bond pads in the second region and a third number of conductive bond pads in the third region is less than the second number, wherein a first area of the first region is greater than a second area of the second region and a third area of the third region is less than the second area. In an embodiment, the second region is spaced between the first region and a third region of the first substrate, wherein conductive bond structures in the first bond structure are completely laterally offset from the third region, wherein a plurality of conductive wires in the first interconnect structure are spaced laterally within the third region.

In various embodiments, the present application a method for forming a device, comprising: forming a first integrated circuit (IC) chip, wherein the first IC chip comprises a first substrate and a first interconnect structure over the first substrate; forming a first bond structure over the first interconnect structure, wherein the first bond structure comprises a first plurality of conductive bond pads in a first region and a second plurality of conductive bond pads in a second region adjacent to the first region, wherein a pitch of the second plurality of conductive bond pads is greater than a pitch of the first plurality of conductive bond pads; and bonding the first IC chip to a second IC chip, wherein the second IC chip comprises a second substrate and a second bond structure, wherein a bond interface is disposed between the first bond structure and the second bond structure. In an embodiment, forming the first bond structure comprises: forming a bond dielectric on the first interconnect structure; patterning the bond dielectric to form a plurality of openings in the bond dielectric; depositing a conductive material in the plurality of openings; and performing a planarization process on the conductive material, thereby defining the first plurality of conductive bond pads and the second plurality of conductive bond pads, wherein top surfaces of the first plurality of conductive bond pads are coplanar with top surfaces of the second plurality of conductive bond pads. In an embodiment, the first plurality of conductive bond pads and the second plurality of conductive bond pads are formed concurrently with one another. In an embodiment, the method further includes: forming a plurality of photodetectors within the first substrate, wherein the plurality of photodetectors are disposed within a device region of the first IC chip, wherein the first region and the second region are spaced laterally within the device region; wherein the first bond structure comprises a third plurality of conductive bond pads in a third region outside of the device region, wherein a pitch of the third plurality of conductive bond pads is greater than the pitch of the second plurality of conductive bond pads; and forming an upper bond element extending through the first substrate to the first interconnect structure, wherein the upper bond element directly overlies at least a portion of the third region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
an interconnect structure on a substrate;
a bond structure over the interconnect structure, wherein the bond structure comprises:
a first plurality of conductive bond pads disposed in a first region; and
a second plurality of conductive bond pads disposed in a second region, wherein the second region is adjacent to at least one side of the first region, wherein a first pitch of the first plurality of conductive bond pads is less than a second pitch of the second plurality of conductive bond pads.

2. The device of claim 1, wherein the first plurality of conductive bond pads are arranged in an array comprising a plurality of columns and a plurality of rows.

3. The device of claim 2, wherein the second plurality of conductive bond pads are arranged in one or more rows and/or one or more columns, wherein a first density of the first plurality of conductive bond pads is greater than a second density of the second plurality of conductive bond pads.

4. The device of claim 1, wherein the first plurality of conductive bond pads contact corresponding first conductive wires in the interconnect structure.

5. The device of claim 4, wherein the second plurality of conductive bond pads contact corresponding second conductive wires in the interconnect structure.

6. The device of claim 4, wherein the second plurality of conductive bond pads are electrically floating, wherein top surfaces of the second plurality of conductive bond pads are offset from conductive structures in the interconnect structure by non-zero distances.

7. The device of claim 1, further comprising:
a plurality of photodetectors disposed in the substrate, wherein the first region directly underlies the plurality of photodetectors.

8. The device of claim 7, wherein the substrate further comprises a third region laterally offset from the plurality of photodetectors, wherein the second region is arranged between the first region and the third region, wherein the bond structure further comprises a third plurality of conductive bond pads in the third region, wherein a third pitch of the third plurality of conductive bond pads is greater than or equal to the second pitch.

9. The device of claim 7, wherein the substrate further comprises a third region laterally offset from the plurality of photodetectors, wherein the second region is arranged between the first region and the third region, wherein the bond structure is devoid of conductive bond structures in the third region.

10. A package, comprising:
a first integrated circuit (IC) chip comprising a first substrate, a first interconnect structure, and a first bond structure, wherein the first bond structure comprises a first plurality of conductive bond pads disposed in a first region of the first substrate and a second plurality of conductive bond pads disposed in a second region of the first substrate, wherein the second region is disposed between the first region and an outer edge of the first IC chip;
a second IC chip comprising a second substrate under the first IC chip, a second interconnect structure, and a second bond structure; and
wherein an interface is disposed between the first bond structure and the second bond structure, wherein a first density of the first plurality of conductive bond pads is greater than a second density of the second plurality of conductive bond pads.

11. The package of claim 10, wherein the first plurality of conductive bond pads are arranged in the first region with a uniform pitch and the second plurality of conductive bond pads are arranged in the second region with a nonuniform pitch, wherein a minimum pitch of the nonuniform pitch is greater than the uniform pitch.

12. The package of claim 10, wherein the first bond structure comprises a single level of conductive elements comprising the first plurality of conductive bond pads and the second plurality of conductive bond pads, wherein bottom surfaces of the first plurality of conductive bond pads are substantially coplanar with bottom surfaces of the second plurality of conductive bond pads.

13. The package of claim 10, wherein the first bond structure comprises a first plurality of dummy conductive bond pads disposed in a third region of the first substrate, wherein the second region is spaced between the third region and the second region, wherein a third density of the first plurality of dummy conductive bond pads is less than the second density.

14. The package of claim 13, wherein the second bond structure comprises a third plurality of conductive bond pads in the first region with the first density, a fourth plurality of conductive bond pads in the second region with the second density, and a second plurality of dummy conductive bond pads in the third region with the third density.

15. The package of claim 13, wherein a first number of conductive bond pads in the first region is greater than a second number of conductive bond pads in the second region and a third number of conductive bond pads in the third region is less than the second number, wherein a first area of the first region is greater than a second area of the second region and a third area of the third region is less than the second area.

16. The package of claim 10, wherein the second region is spaced between the first region and a third region of the first substrate, wherein conductive bond structures in the first bond structure are completely laterally offset from the third region, wherein a plurality of conductive wires in the first interconnect structure are spaced laterally within the third region.

17. A method of forming a device, comprising:
forming a first integrated circuit (IC) chip, wherein the first IC chip comprises a first substrate and a first interconnect structure over the first substrate;
forming a first bond structure over the first interconnect structure, wherein the first bond structure comprises a first plurality of conductive bond pads in a first region and a second plurality of conductive bond pads in a second region adjacent to the first region, wherein a pitch of the second plurality of conductive bond pads is greater than a pitch of the first plurality of conductive bond pads; and
bonding the first IC chip to a second IC chip, wherein the second IC chip comprises a second substrate and a second bond structure, wherein a bond interface is disposed between the first bond structure and the second bond structure.

18. The method of claim 17, wherein forming the first bond structure comprises:
forming a bond dielectric on the first interconnect structure;
patterning the bond dielectric to form a plurality of openings in the bond dielectric;
depositing a conductive material in the plurality of openings; and
performing a planarization process on the conductive material, thereby defining the first plurality of conductive bond pads and the second plurality of conductive bond pads, wherein top surfaces of the first plurality of conductive bond pads are coplanar with top surfaces of the second plurality of conductive bond pads.

19. The method of claim 18, wherein the first plurality of conductive bond pads and the second plurality of conductive bond pads are formed concurrently with one another.

20. The method of claim 17, further comprising:
forming a plurality of photodetectors within the first substrate, wherein the plurality of photodetectors are disposed within a device region of the first IC chip, wherein the first region and the second region are spaced laterally within the device region;
wherein the first bond structure comprises a third plurality of conductive bond pads in a third region outside of the device region, wherein a pitch of the third plurality of conductive bond pads is greater than the pitch of the second plurality of conductive bond pads; and
forming an upper bond element extending through the first substrate to the first interconnect structure, wherein the upper bond element directly overlies at least a portion of the third region.
